(19) United States
(12) Patent Application Publication
(10) Pub. No.: US 2006/0131676 A1
(43) Pub. Date: Jun. 22, 2006

(54) Semiconductor device and manufacturing method thereof

(76) Inventors: Tomohiro Saito, Yokohama-Shi (JP); Kyoichi Suguro, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/289,694

(22) Filed: Nov. 30, 2005

(30) Foreign Application Priority Data
Nov. 30, 2004 (JP) 2004-346957

(51) Int. Cl. H01L 29/94; H01L 21/3205

(52) U.S. Cl. 257/412; 257/369; 257/374; 257/413; 438/585; 257/E29.157

(57) ABSTRACT

A semiconductor device includes: a substrate having a silicon layer on at least a surface thereof; an insulating film formed on the silicon layer; a first electrode formed on the insulating film and including a first metal thin film and a film having silicon formed on the first metal thin film; and a second electrode formed on the insulating film and including a metal silicide which is an alloy of the first metal and silicon, and a film having silicon formed on the metal silicide, wherein the first electrode is formed on a surface of the first metal thin film, and further includes a compound which controls a reaction of the first metal and the silicon.

### CROSS REFERENCE TO RELATED APPLICATION

This application claims benefit of priority under 35USC §119 to Japanese Patent Application No. 2004-346957, filed on Nov. 30, 2004, the contents of which are incorporate by reference herein.

### BACKGROUND OF THE INVENTION

1. Field of the Invention

The present invention relates to a semiconductor device and a manufacturing method thereof, and is intended, for example, for a metal insulator semiconductor field effect transistor (MISFET) type semiconductor device using a metal electrode for a gate.

2. Related Background Art

With advances in miniaturization of silicon semiconductor transistors, effects of a gate depletion layer are not negligible in conventional transistors using polycrystalline silicon as an electrode material, and metal gate transistors are thus being developed which use a metal material for the electrode material. In the metal gate transistor, a threshold voltage is decided by the work function of a gate electrode.

However, if the threshold value of the transistor is decreased to enhance its performance, a plurality of electrode materials has to be prepared for a dual metal gate electrode having different work functions in an NMOS transistor and a PMOS transistor, which causes a problem that a manufacturing process becomes complicated. Further, in the manufacturing process, the formation and exfoliation of the electrode material on a gate insulating film have to be performed a plurality of times, and there is therefore a problem that reliability is lower in the insulating film on the side of the electrode where the exfoliation and reformation of the film have been carried out.

### SUMMARY OF THE INVENTION

According to a first aspect of the present invention, there is provided a semiconductor device comprising:

a substrate having a silicon layer on at least a surface thereof;

an insulating film formed on the silicon layer;

a first electrode formed on the insulating film and including a first metal thin film and a film having silicon formed on the first metal thin film; and

a second electrode formed on the insulating film and including a metal silicide which is an alloy of the first metal and silicon, and a film having silicon formed on the metal silicide,

wherein the first electrode further includes a compound which controls a reaction of the first metal and the silicon, and the compound being formed on a surface of the first metal thin film.

According to a second aspect of the present invention, there is provided a semiconductor device comprising:

a substrate having a silicon layer on at least a surface thereof;

an insulating film formed on the silicon layer;

a first electrode formed on the insulating film and including a first metal silicide which is an alloy of a first metal, a second metal different from the first metal, and silicon; and

a second electrode formed on the insulating film and including a second metal silicide which is an alloy of the first metal and silicon.

According to a third aspect of the present invention, there is provided a method of manufacturing a semiconductor device comprising:

forming an insulating film on a silicon layer of a substrate having the silicon layer on at least a surface thereof;

forming a first metal thin film made of a first metal over the insulating film;

selectively subjecting a region for a first electrode to a surface treatment, the region for the first electrode being included in a first metal thin film formation region;

forming polycrystalline silicon or amorphous silicon over the substrate; and

reacting the first metal with the polycrystalline silicon or amorphous silicon in a region for a second electrode, the region for the second electrode being included in the first metal thin film region,

wherein the surface treatment is a treatment to control the reaction of the first metal and the polycrystalline silicon or of the first metal and the amorphous silicon.

According to a fourth aspect of the present invention, there is provided a method of manufacturing a semiconductor device, comprising:

forming an insulating film on a silicon layer of a substrate having the silicon layer on at least a surface thereof;

forming a metal silicide including a first metal over the insulating film;

selectively forming a thin film including a second metal in a part of a region on the metal silicide, the second metal being able to react with the first metal; and

reacting a metal silicide including the first metal with the thin film including the second metal to form an alloy having a work function different from a work function of the first metal.

### BRIEF DESCRIPTION OF THE DRAWINGS

In the accompanying drawings:

FIG. 1 is a sectional view showing essential parts of a semiconductor device according to a first embodiment of the present invention;

FIGS. 2 to 8 are schematic sectional views to explain a method of manufacturing the semiconductor device shown in FIG. 1;

FIGS. 9 to 15 are schematic sectional views to explain a method of manufacturing the semiconductor device shown in FIG. 1 in a first modification;

FIG. 16 is a sectional view showing essential parts of the semiconductor device shown in FIG. 1 in the first modification;

FIG. 17 is a sectional view showing essential parts of the semiconductor device shown in FIG. 1 in a second modification;

FIG. 18 is a sectional view showing essential parts of the semiconductor device according to a second embodiment of the present invention;

FIGS. 19 to 23 are schematic sectional views to explain a method of manufacturing the semiconductor device shown in FIG. 18;

FIG. 24 is a sectional view showing essential parts of the semiconductor device according to a third embodiment of the present invention; and

FIGS. 25 to 32 are schematic sectional views to explain a method of manufacturing the semiconductor device shown in FIG. 24.

### DETAILED DESCRIPTION OF THE INVENTION

Embodiments of the present invention will hereinafter be described in reference to the drawings. It is to be noted that in the following drawings, the same reference numbers are assigned to the same parts, and redundant explanation thereof will be omitted accordingly.

### (1) FIRST EMBODIMENT

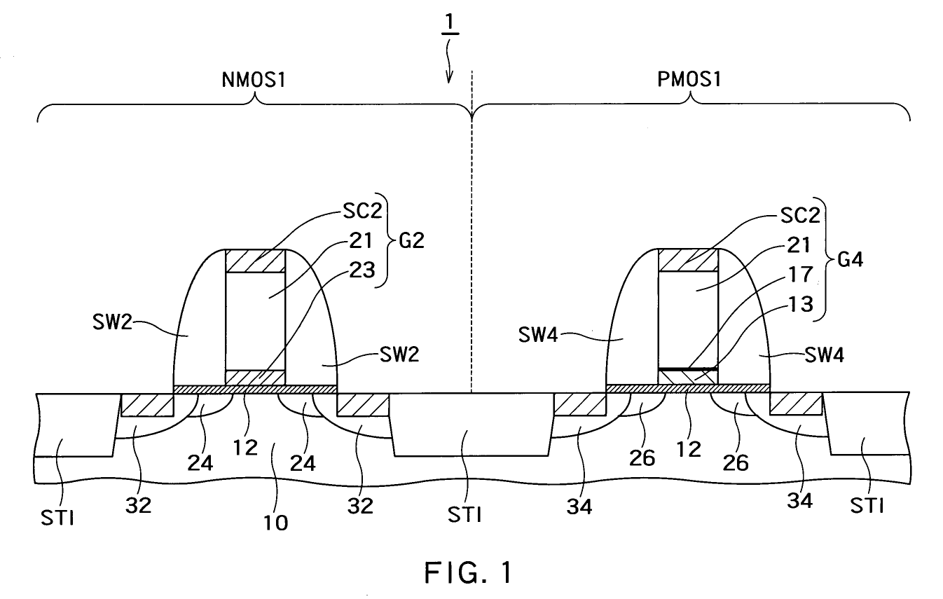

FIG. 1 is a sectional view showing the configuration of essential parts of a semiconductor device according to a first embodiment of the present invention. A semiconductor device 1 shown in FIG. 1 comprises a silicon substrate 10, and a CMOS transistor formed in a silicon layer surface portion of the silicon substrate 10. The CMOS transistor comprises a PMOS transistor 1 and an NMOS transistor 1 which are formed of shallow trench isolation type insulating films (hereinafter, simply referred to as STIS) respectively in a PMOS region and an NMOS region separated from each other or from other elements.

The PMOS transistor 1 includes a gate electrode G4 formed on the substrate 10 via a gate insulating film 12; a source/drain electrode 34 formed in a peripheral part within the PMOS region proximately to the STI and provided with silicide on its surface; and a lightly doped drain (hereinafter, referred to as LDD) impurity diffused layer formed around these electrodes and in a channel region placed between these electrodes. The gate electrode G4 includes a tungsten (W) film 13 formed immediately on the gate insulating film 12; a tungsten nitride (WN) 17; a polycrystalline silicon 21 formed on the tungsten nitride (WN) 17; and a silicide SC2 formed on top of the polycrystalline silicon 21. In the present embodiment, the gate electrode G4 corresponds, for example, to a first electrode. Tungsten (W) corresponds, for example, to a first metal; the tungsten (W) film 13 corresponds, for example, to a first metal thin film; and the tungsten nitride (WN) 17 corresponds, for example, to a compound which controls the reaction of the first metal and polycrystalline silicon. A gate sidewall SW4 is formed around the gate electrode G4.

The NMOS transistor 1 includes a gate electrode G2 formed on the substrate 10 via the gate insulating film 12; a source/drain electrode 32 formed in the peripheral part within the PMOS region proximately to the STI and provided with silicide on its surface; and an LDD layer formed around these electrodes and in a channel region placed between these electrodes. The gate electrode G2 includes a tungsten silicide film (WSix) 23 formed immediately on the gate insulating film 12; the polycrystalline silicon 21 formed on the tungsten silicide film (WSix) 23; and the silicide SC2 formed on top of the polycrystalline silicon 21. In the present embodiment, the gate electrode G2 corresponds, for example, to a second electrode. A gate sidewall SW2 is protectively formed around the gate electrode G2.

The semiconductor device 1 of the present embodiment is characterized in that between the tungsten (W) film 13 and the polycrystalline silicon 21 in the gate electrode G4 out of the gate electrodes G2, G4 of the two transistors constituting the CMOS, there is formed the tungsten nitride (WN) 17 which is a compound to restrain the reaction between these members, so that the gate electrodes G2, G4 have mutually different work functions. In the present embodiment, the work function of the gate electrode G2 is shifted lower than the work function of the gate electrode G4, and the shift amount is from 0.4 eV to 0.8 eV, for example. Such a difference in the work function decreases a threshold value of the NMOS transistor, resulting in enhanced performance of the semiconductor device 1.

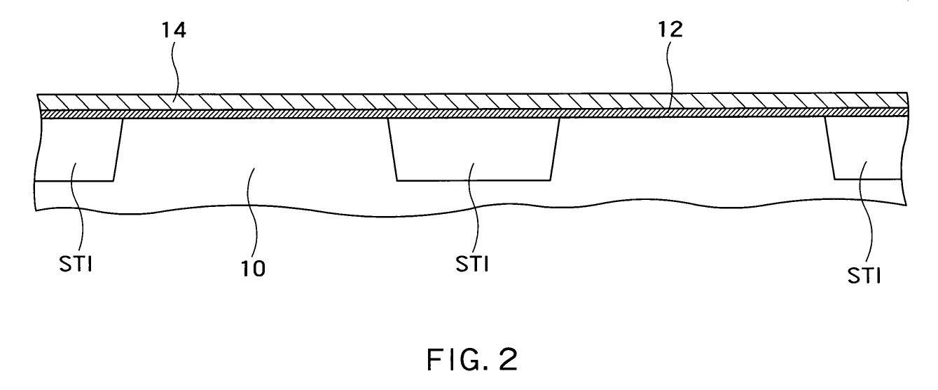

A method of manufacturing the semiconductor device 1 shown in FIG. 1 will be described referring to FIG. 2 to FIG. 8.

As shown in FIG. 2, an isolation insulating film STI is first formed in a surface layer of the silicon substrate 10 in a known manner. Although not specifically shown, the isolation insulating film STI can be formed, for example, in the following manner. A silicon nitride film which becomes a mask is deposited on the silicon substrate 10 via a buffer film, and the silicon nitride film, the buffer film and the silicon substrate 10 are selectively removed by etching to a predetermined depth using a pattern transfer method with a resist. After removing the resist and depositing a silicon oxide film all over the surface, planarization is implemented by chemical mechanical polishing (hereinafter, simply referred to as CMP) or the like. The mask of the silicon nitride film is removed to form the STI.

Next, the gate insulating film 12 is formed all over the surface of the silicon substrate 10. The formation of the gate insulating film 12 is enabled, for example, by thermal oxidation of the silicon substrate to form a thermally oxidized film, or by forming a nitride film, or else, it is also possible to use a method in which a high dielectric film is formed after a surface treatment. Subsequently, a thin film of tungsten (W) of about 5 to about 10 nm is formed all over the surface by a chemical vapor deposition (CVD) method or a Physical vapor Deposition (PVD) method.

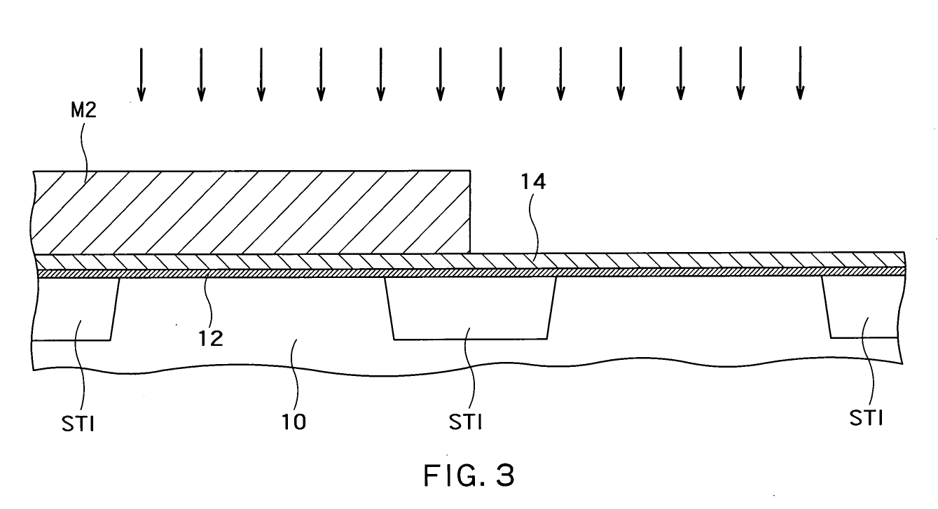

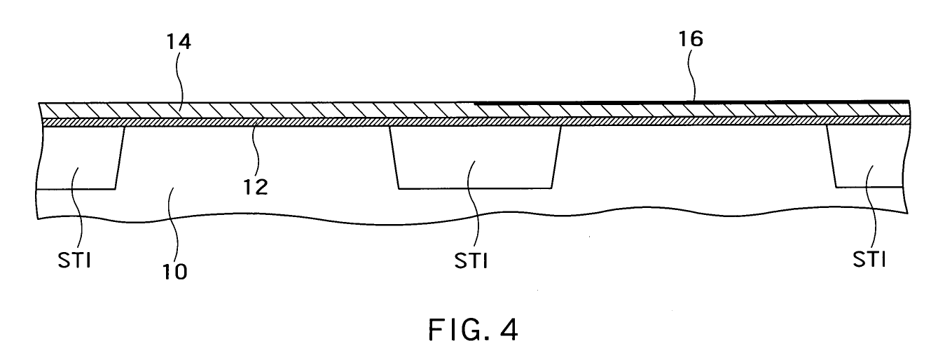

Then, the surface of the tungsten thin film is nitrided only in a region where the PMOS is formed, for example. A method of selective nitriding only in a desired region is realized in the following manner. First, as shown in FIG. 3, a method of depositing a film formed at low temperature is used to form a silicon oxide film as a mask material, and the silicon oxide film is processed by patterning and etching using the resist to form a silicon oxide film mask M2. A dilute hydrofluoric acid treatment may be used for the etching, or anisotropic etching such as reactive ion etching (hereinafter, simply referred to as RIE) may be performed. Then, the exposed surface of a tungsten thin film 14 is nitrided by a plasma treatment or the like. Finally, the silicon oxide film mask M2 is removed by the dilute hydrofluoric acid treatment or the like, thereby completing the surface nitriding of the tungsten thin film in the desired region and allowing a tungsten nitride film 16 to be obtained, as shown in FIG. 4. In addition to the method described above, for example, a silicon nitride film may be selectively formed on the tungsten thin film only in the desired region, and nitrogen may be diffused into tungsten from the nitride film by a thermal process. The thermal process includes a photothermal treatment such as a flash lamp treatment.

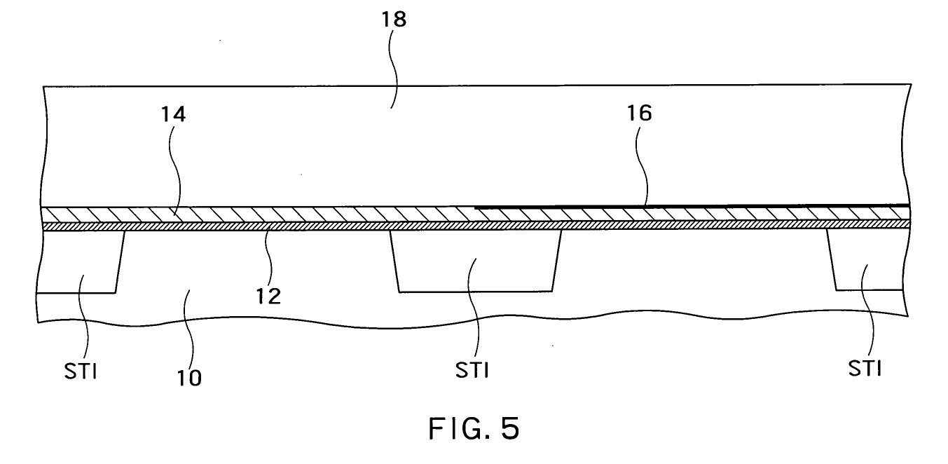

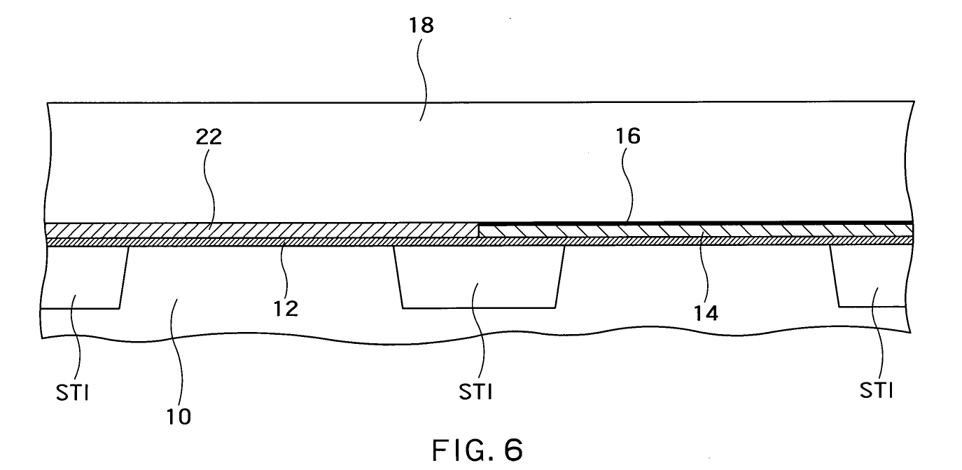

Next, as shown in FIG. 5, a polycrystalline silicon 18 is formed all over the surface. By applying heat at 650° C. or higher, the tungsten thin film 14 in the region where the surface is not nitrided reacts with polycrystalline silicon to become a tungsten silicide film (WSix) 22, as shown in FIG. 6. On the other hand, the nitrided region does not react with silicon because of a barrier of the tungsten nitride (WN) 16 on the surface.

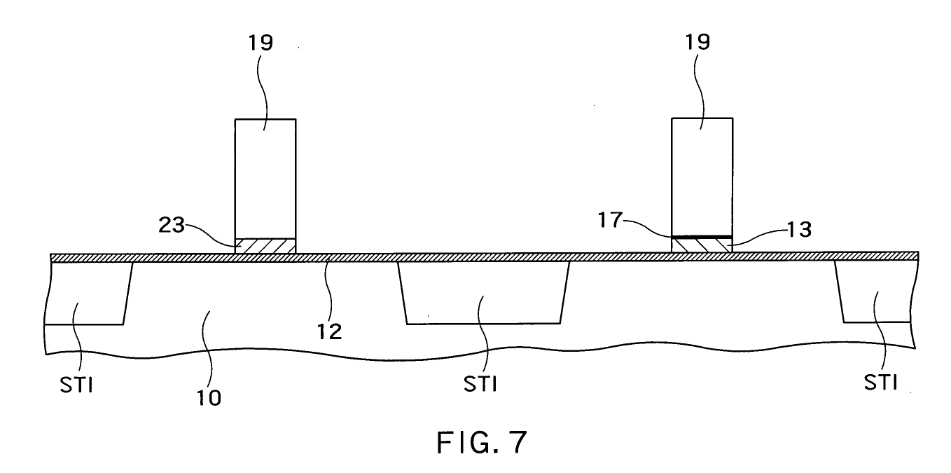

Subsequently, the polycrystalline silicon 18, the tungsten silicide film (WSix) 22, the tungsten nitride 17 and the tungsten thin film 13 are selectively removed by the pattering using the resist or the like and by the anisotropic etching such as the RIE, in order to process into a gate shape as shown in FIG. 7.

It is to be noted that the gates G2, G4 may be doped with impurities at this point. Also, a polycrystalline silicon film into which impurities have previously been introduced (e.g., P-doped polycrystalline silicon) may be used.

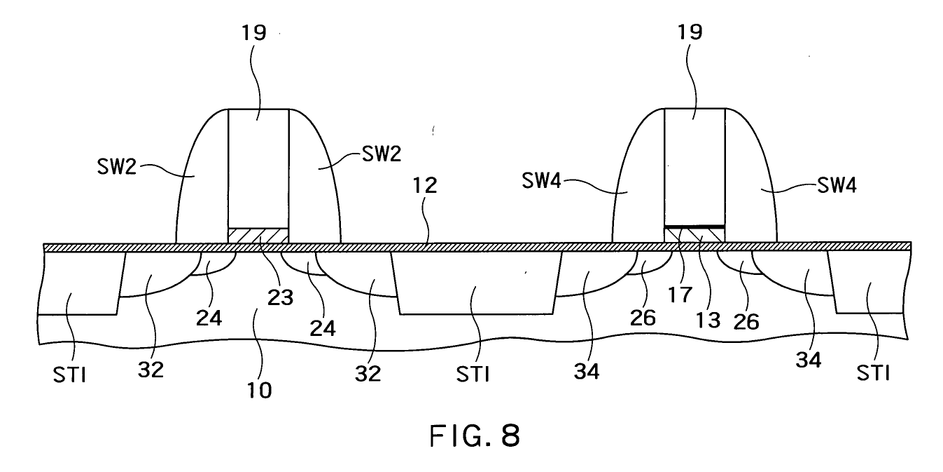

Furthermore, as shown in FIG. 8, after LDD layers 24, 26 are formed in a known manner, the sidewalls SW2, SW4 are formed around the gate electrodes G2, G4, respectively. Impurities are injected using the sidewalls SW2, SW4 as the masks to form impurity diffused layers which will be source/drains 32, 34 (see FIG. 1). At the same time, impurities are also introduced into polycrystalline silicon 19 of the gate electrodes G2, G4. The thermal process is performed to diffuse and activate the impurities introduced into the regions of the source/drains. At the same time, impurity ions introduced into the gate electrodes G2, G4 are diffused. In the electrode G2 including polycrystalline silicon and tungsten silicide (Poly-Si/WSix) on the side of the NMOS transistor 1, a dopant (e.g., P or As) is diffused into an interface between tungsten silicide (WSix) and the gate insulating film 12, so that the work function of tungsten silicide (WSix) is shifted. Further, the work function of the electrode G4 including polycrystalline silicon and tungsten nitride/tungsten (Poly-Si/WN/W) on the side of the PMOS 1 is decided by tungsten. It is to be noted that in the method described above, the electrode G4 has the same kind and the same concentration of impurities as those of the source/drain impurity diffused layer 34. When it is desired to interchange the kind and concentration of impurities injected into the electrode G4 with the kind and concentration of impurities of the source/drain region, there is also a method available in which polycrystalline silicon is deposited all over the surface before introducing impurities, on which the silicon nitride film is deposited as the mask material to perform a gate process.

In this way, after the impurity diffused layer is formed in the region of the source/drain by ion injection using the gate and sidewall as the masks and by the subsequent thermal process, silicide is formed in these impurity diffused layer parts. Silicide is also formed in the gate electrode at the same time as the source/drain impurity diffused layer, but the work function of the gate electrode itself is decided by the tungsten silicide film (WSix) 23 which is in contact with the gate insulating film 12 and into which impurities have been introduced, and by the tungsten nitride film 17 formed on the surface of the tungsten film 13 by the surface treatment. Therefore, the polycrystalline silicon part on top of the gate electrode formed simultaneously with the source/drain only contributes to reduced resistance of the gate electrode.

Subsequently, an interlayer film is deposited all over the surface as in an ordinary transistor forming process, and then contact wires are formed to complete the transistor (not shown). Thus, according to the present embodiment, use is made of the WSix electrode into which impurities are introduced in the region of the NMOS, and the tungsten electrode is used in the region of the PMOS, so that the threshold values of the respective transistors can be decreased (as compared to the case where an electrode of a midgap is used). Moreover, since there is no step of forming again the electrode material on the insulating film as has heretofore been done, it is possible to form a CMOS with improved reliability.

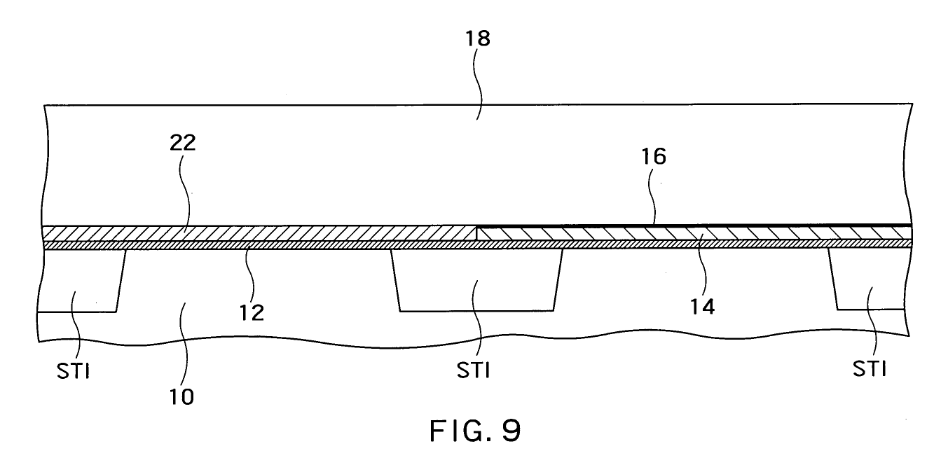

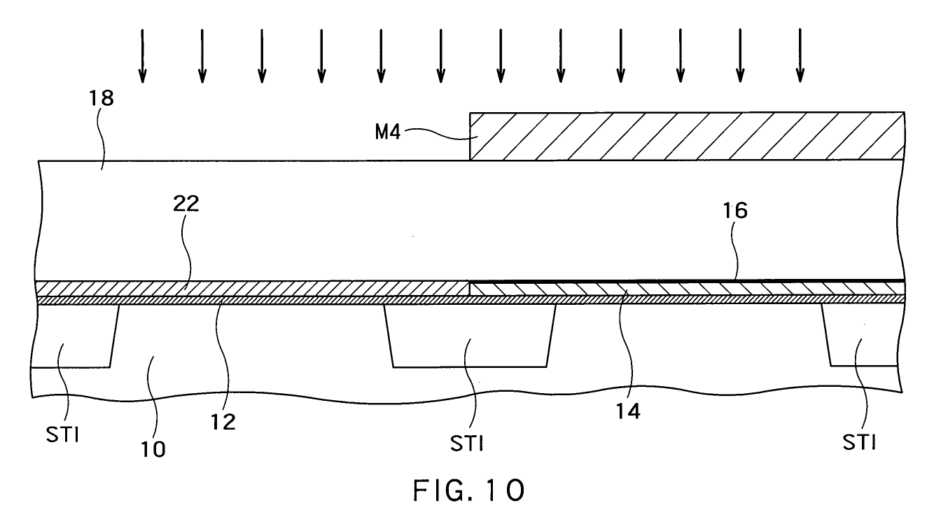

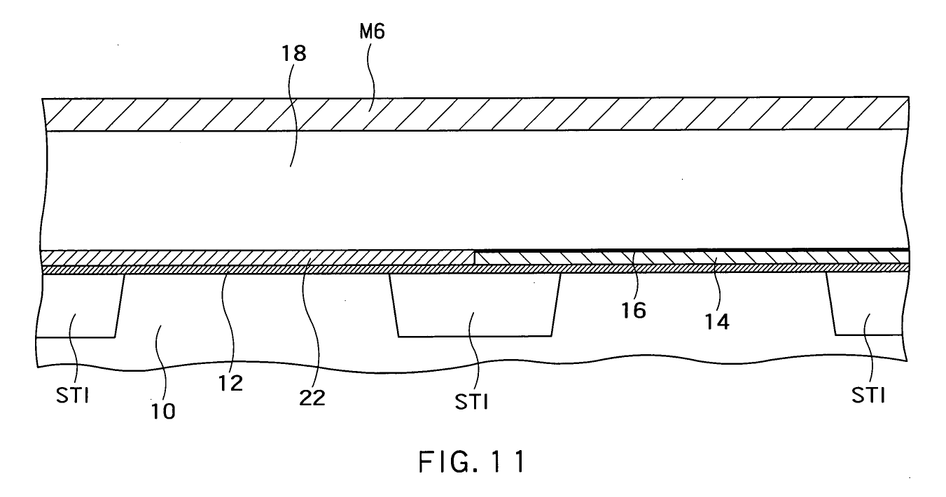

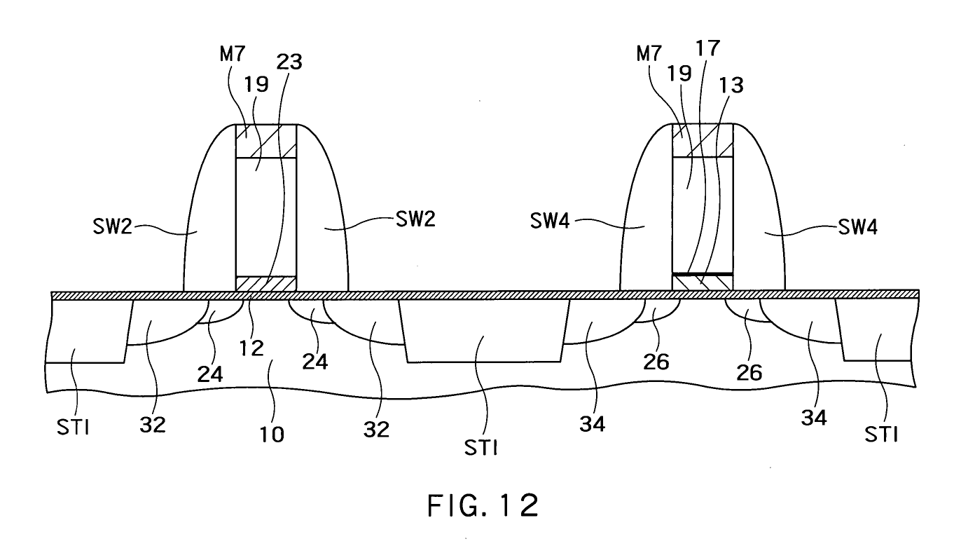

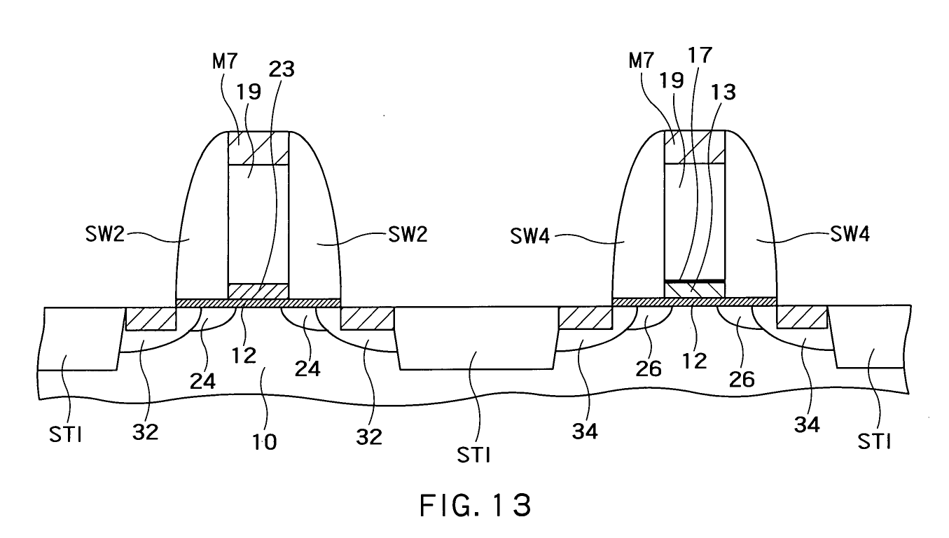

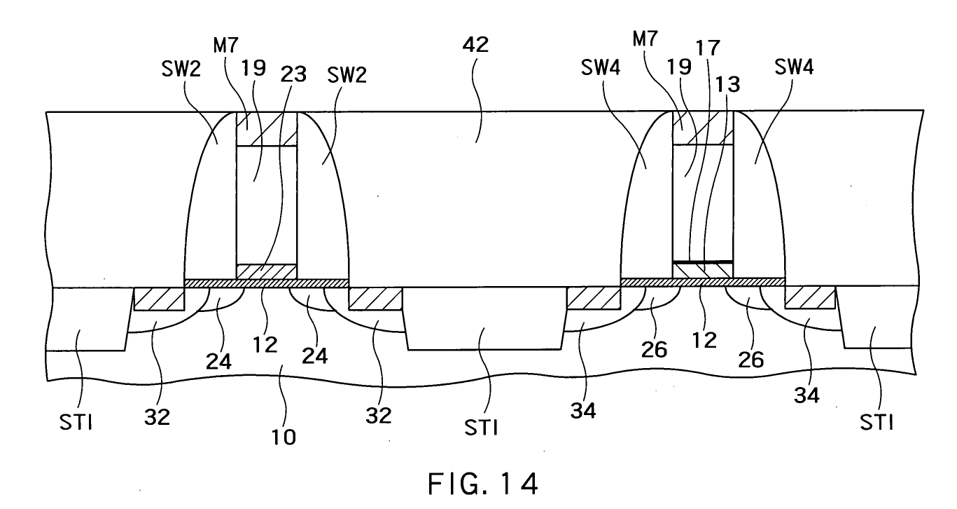

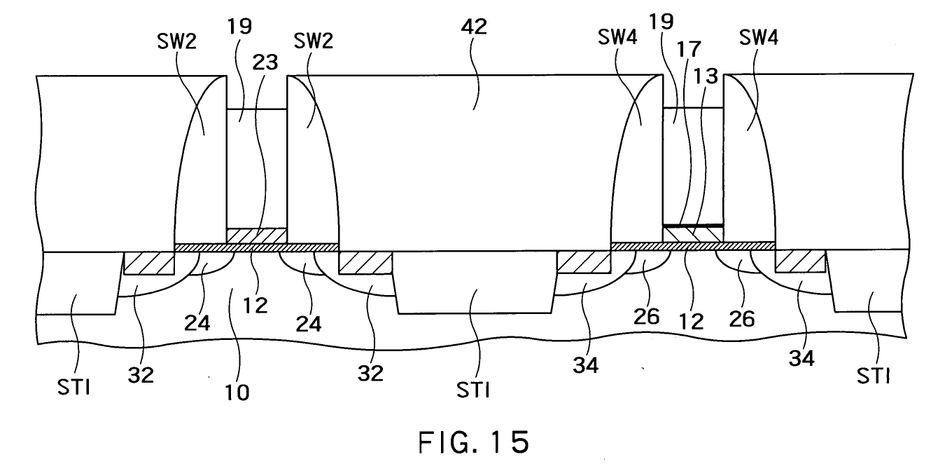

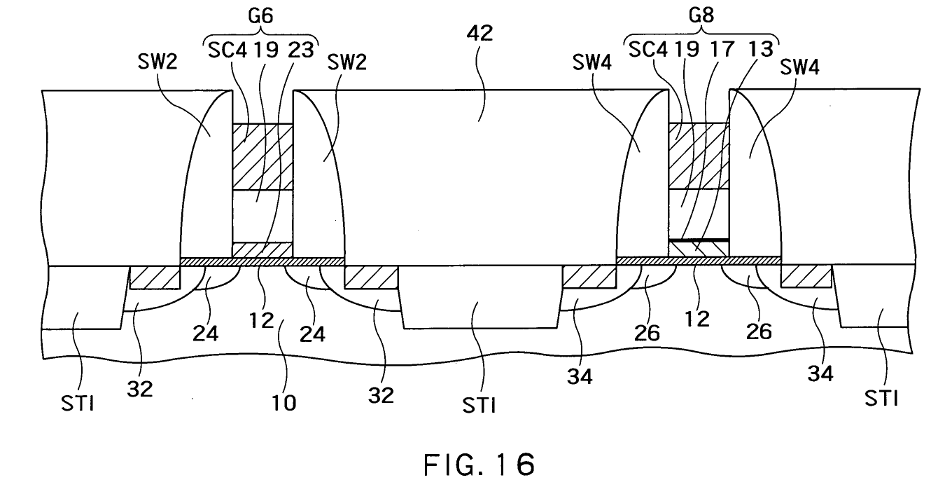

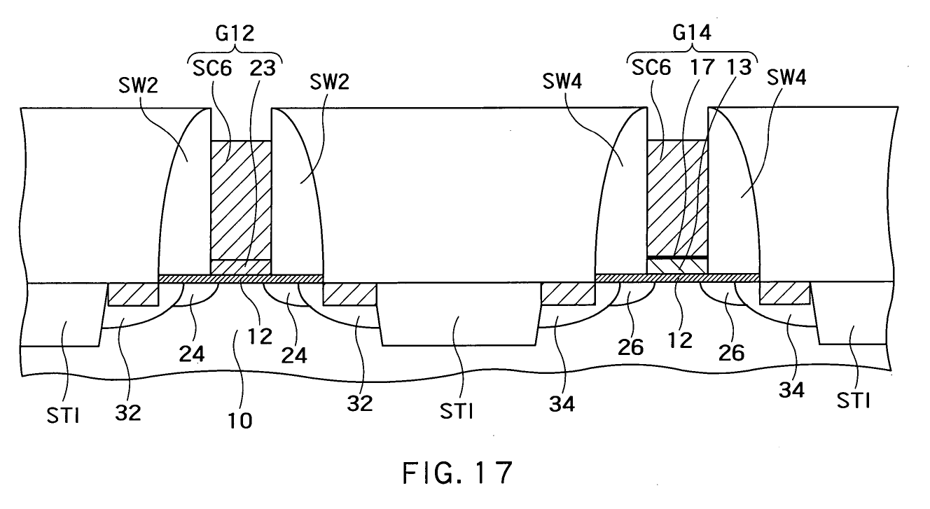

Silicide in the gate part can also be formed separately from the silicide formed in the source/drain region. A specific example of this kind will be described as a modification of the present embodiment with reference to FIG. 9 to FIG. 17. In this case, first, as shown in FIG. 9, the tungsten silicide film (WSix) 22 is formed in the NMOS region in the thermal process after the polycrystalline silicon 18 has been formed all over the surface, and then a mask M4 is deposited as shown in FIG. 10 to introduce impurities, and then, as shown in FIG. 11, SiN is deposited as a mask M6 so as not to form silicide on the polycrystalline silicon electrode. Subsequently, as shown in FIG. 12, the gate processing and the formation of the source/drain impurity diffused layers 32, 34 and of the LDD layers 24, 26 are performed, and as further shown in FIG. 13; the sidewalls SW2, SW4 and source/drain silicide are formed as in the ordinary manufacturing process. Subsequently, as shown in FIG. 14, for example, a silicon oxide film 42 is formed as the interlayer film all over the surface before the planarization such as the CMP, and an upper surface of a SiN mask M7 on the polycrystalline silicon 19 of the gate electrode is exposed. As shown in FIG. 15, the polycrystalline silicon 19 of the gate electrode is exposed by removing the SiN mask M7 from each gate electrode. Then, a silicide process is performed again, so that a silicide SC4 is formed in the gate electrode part as in a semiconductor device 2 shown in FIG. 16. In this first modification, a material different from that of the source/drain electrode can also be used for the silicide material of the gate electrode. Further, as in a semiconductor device 3 in a second modification shown in FIG. 17, for example, if the part of the gate electrode in the NMOS region is completely made of silicide, a so-called fully silicided gate electrode G12 is formed. Nickel (Ni), cobalt (Co), titan (Ti), palladium (Pd) and the like can be used for the silicide material.

### (2) SECOND EMBODIMENT

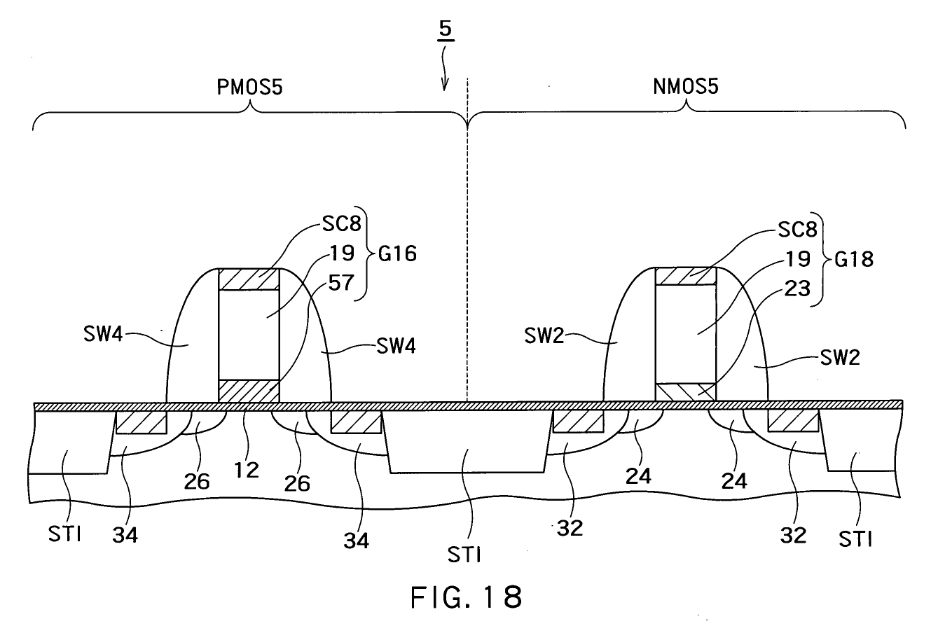

Next, a second embodiment of the present invention will be described referring to FIG. 18 to FIG. 23.

FIG. 18 is a sectional view showing the configuration of essential parts of a semiconductor device 5 of the present embodiment. In FIG. 18, a PMOS transistor 5 is illustrated on the left side of the drawing, and an NMOS transistor 5 is illustrated on the right side. The semiconductor device 5 of the present embodiment is characterized by the structure of a gate electrode G16 of the PMOS transistor and by including, instead of the tungsten nitride (WN) 17 in the semiconductor device 1 of FIG. 1, a WxPtySiz film (x+y+z=1) 57 obtained by the reaction of tungsten silicide and platinum (Pt). In the present embodiment, the gate electrodes G16, G18 correspond, for example, to the first and second electrodes, respectively. Further, tungsten (W) corresponds, for example, to the first metal; platinum (Pt) corresponds, for example, to a second metal different from the first metal; and the WxPtySiz film 57 corresponds, for example, to a first metal silicide which is an alloy of the first metal, the second metal and silicon.

In this way, the platinum silicide WxPtySiz film 57 containing tungsten also allows the work function of the gate electrode to be shifted to decrease the threshold value of the CMOS. This provides a high-performance semiconductor device. Other points of the semiconductor device 5 are substantially the same as the semiconductor device 1 shown in FIG. 1. It is to be noted that platinum silicide (PtSi) may be formed on tungsten silicide (WSi).

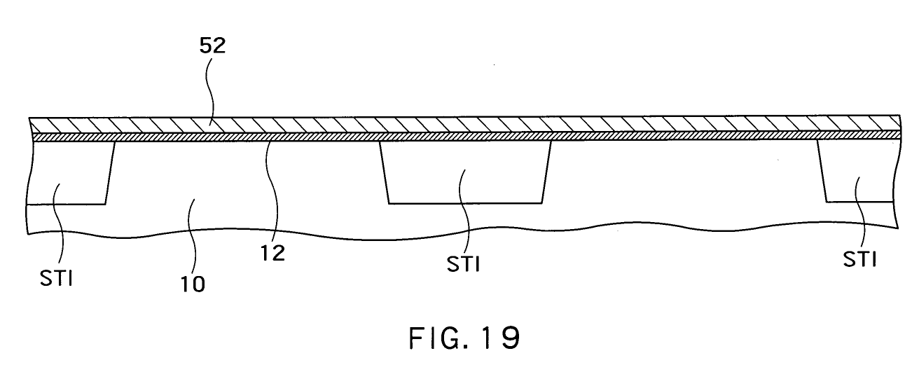

The semiconductor device 5 of the present embodiment can be manufactured without causing damage to the gate insulating film, as in the embodiment described above. A specific method of manufacturing the semiconductor device 5 will be described referring to FIG. 19 to FIG. 23.

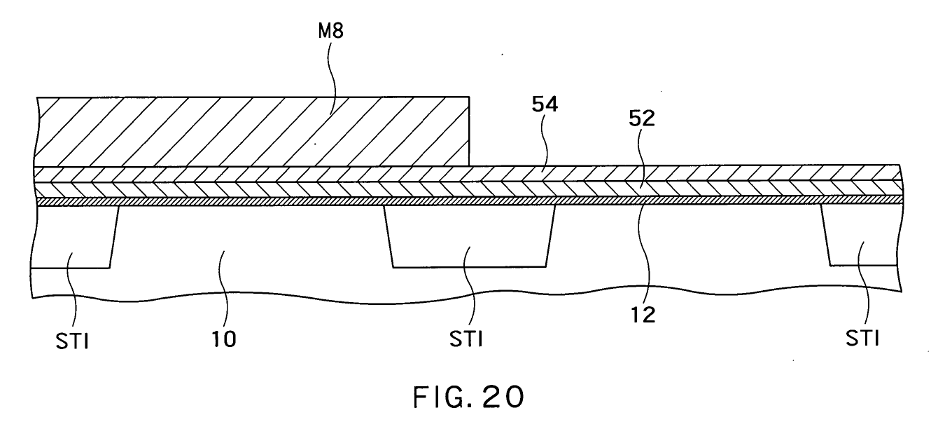

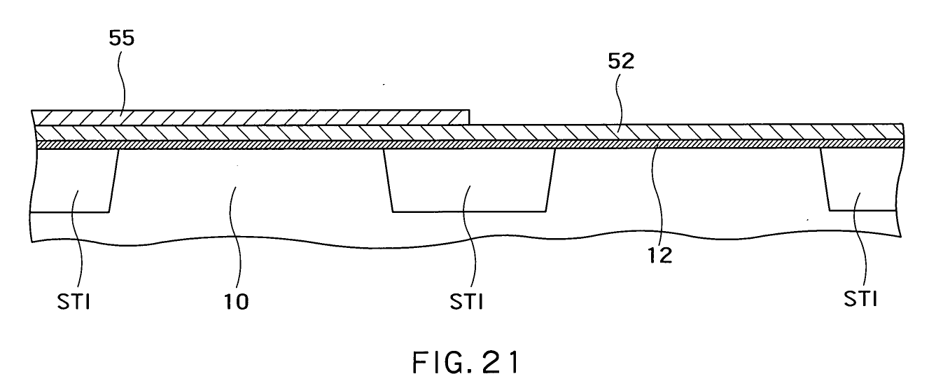

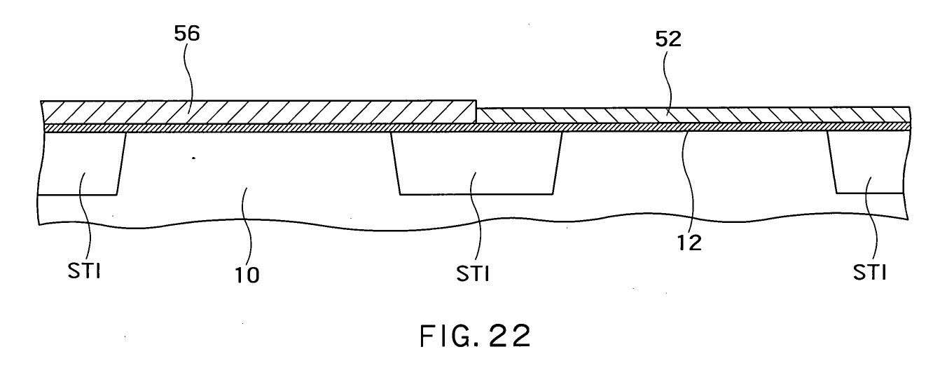

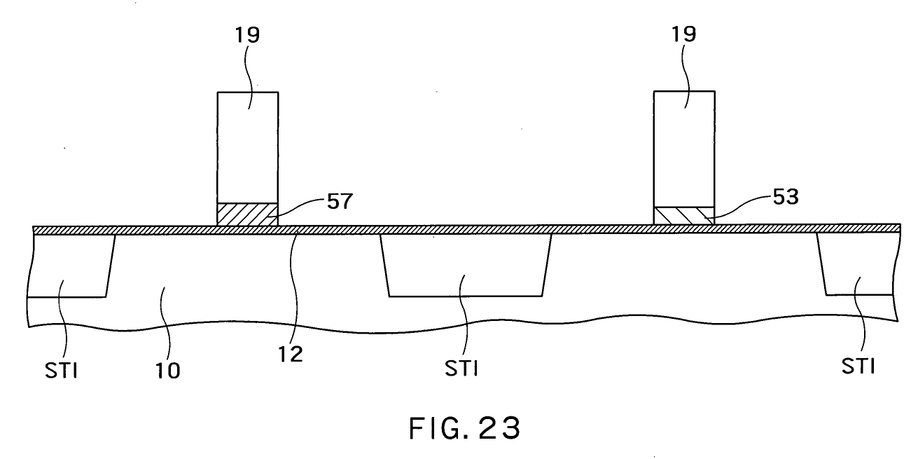

As shown in FIG. 19, the gate insulating film 12 is first formed on the silicon substrate 10 in which the isolation insulating film (STI) has been formed in a known manner, and then a tungsten silicide (WSi) film 52 of about 5 to about 10 nm is formed all over the surface by a CVD method. Subsequently, as shown in FIG. 20, a thin film of platinum (Pt) 54 is formed on the tungsten silicide (WSi) film 52 using, for example, a sputtering method. After the silicon oxide film is deposited as the mask material all over the surface, the silicon oxide film is selectively removed by patterning and etching with the resist so that the region where the PMOS is formed only remains, for example. With the obtained silicon oxide film as a mask M8, the platinum (Pt) thin film 54 is selectively removed by etching, so that a platinum (Pt) thin film 55 remains only in the desired region, in the present embodiment, in the region of the PMOS. Subsequently, as shown in FIG. 21, the thermal process is applied after the silicon oxide film mask M8 is removed by hydrofluoric acid or the like, so that, as shown in FIG. 22, platinum (Pt) reacts with the tungsten silicide (WSi) thin film only in the desired region (e.g., the PMOS region), resulting in a platinum silicide (WxPtySiz) film 56 (x+y+z=1) containing tungsten. Subsequently, the polycrystalline silicon 18 is deposited all over the surface. In this case, WSi may be formed all over the surface instead of polycrystalline silicon. Then, as shown in FIG. 23, a laminate of the polycrystalline silicon 18 and the tungsten silicide film (WSix) 52 and a laminate of the platinum silicide film containing tungsten (WxPtySiz) 56 and the polycrystalline silicon 18 are processed into a gate shape by the pattering with the resist or the like and by the anisotropic etching such as the RIE, thereby obtaining a laminate of a tungsten silicide film (WSix) 53 and the polycrystalline silicon 19 and a laminate of the platinum silicide (WxPtySiz) film 57 and the polycrystalline silicon 19, respectively.

Furthermore, after the impurity diffused layers having an LDD structure are formed in a known manner, the sidewalls SW2, SW4 are formed around the gate electrodes G16, G18, respectively. Then, while impurities are injected to form the impurity diffused layer of the source/drain, impurities are also introduced into the polycrystalline silicon 19 within the gate electrodes G16, G18 at the same time. The diffusion of the introduced impurities and the activation of the impurity diffused layer are performed by implementing the thermal process. At the same time, impurity ions introduced into the gate electrodes G16, G18 are also diffused. In the electrode G18 including polysilicon/tungsten silicide (Poly-Si/WSi) on the NMOS side, a dopant (e.g., P or As) is diffused into a film interface between the tungsten silicide (WSx) 23 and the gate insulating film 12, so that the work function of tungsten silicide (WSx) 23 is shifted lower, for example, to about 4.1 eV. On the other hand, the work functions of platinum silicide containing tungsten on the PMOS side and of the gate electrode G18 containing polycrystalline silicon (Poly-Si/WxPtySiz) are decided by platinum silicide containing tungsten (WxPtySiz). It is to be noted that in the method described above, impurities of the same kind as that of the source/drain impurity diffused layer are introduced into polycrystalline silicon of the gate electrodes G16, G18, and the concentration of pure substances thereof will also be the same. When it is desired to change the kind and concentration of impurities, for example, there is also a method available in which polycrystalline silicon is deposited all over the surface before introducing impurities, on which the silicon nitride film is deposited as the mask material to perform the gate process.

Subsequently, after the impurity diffused layers 32, 34 for the source/drain electrodes are formed, silicide is formed in the part of the impurity diffused layers 32, 34, thereby providing the semiconductor device shown in FIG. 18. Silicide is also formed in the gate electrodes G16, G18 at the same time as silicide in the source/drain region. However, the work function of the gate electrode itself is decided by the tungsten silicide film (WSix) (the gate G18) which is in contact with the gate insulating film and into which impurities have been introduced, and by the film of platinum silicide containing tungsten and polycrystalline silicon (Poly-Si/WxPtySiz film) (the gate 16), and silicide on the gate electrode only contributes to reduced resistance of the gate electrode in the polycrystalline silicon part. It is to be noted that when it is desired to interchange the kind of silicide between the source/drain electrode and the gate electrode or to interchange the thickness of silicide, the silicon nitride film may be formed on polycrystalline silicon before the gate process as in the first embodiment described above.

Subsequently, the interlayer film can be deposited all over the surface as in the ordinary transistor forming process, and then the contact wires can be formed to complete the transistor.

### (3) THIRD EMBODIMENT

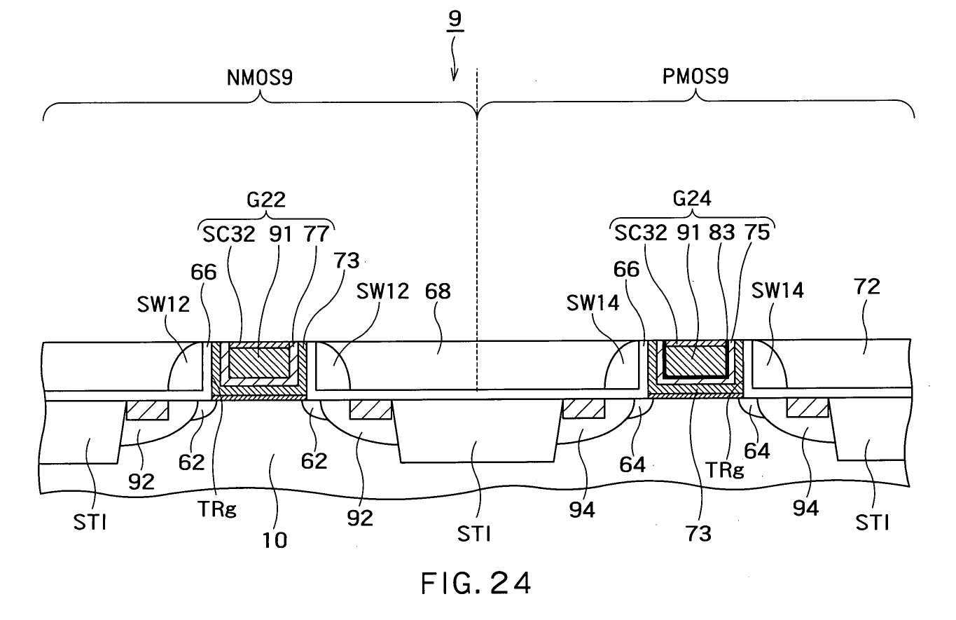

FIG. 24 is a sectional view showing essential parts of the semiconductor device according to a third embodiment of the present invention. In contrast with the embodiments described above, a semiconductor device 9 shown in FIG. 24 implements the present invention using a damascene gate process.

Specifically, a trench TRg which is a dummy gate is left on the CMOS region isolated by the STI formed on the surface part of the silicon substrate 10, so as to form a silicon nitride layer 66, sidewalls SW12, SW14 and an interlayer insulating film 68.

In the gate trench TRg in the NMOS region, there are formed, on its bottom surface and inner surface, a gate insulating film 73, a tungsten silicide (WSi) 77, a polycrystalline silicon 91 and a silicide SC32, so as to sequentially fill the trench TRg. The tungsten silicide (WSi) 77, the polycrystalline silicon 91 and the silicide SC32 constitute a gate electrode G22. In the present embodiment, the gate electrode G22 corresponds, for example, to the second electrode, and tungsten (W) corresponds, for example, to the first electrode.

In the gate trench TRg in the PMOS region, there are formed, on its bottom surface and inner surface, the gate insulating film 73, a tungsten (W) thin film 75, a tungsten nitride (WN) 83, the polycrystalline silicon 91 and the silicide SC32, so as to sequentially fill the trench TRg. The tungsten thin film 75, the tungsten nitride 83, the polycrystalline silicon 91 and the silicide SC32 constitute a gate electrode G24. In the channel region surrounded by the STI within the surface part of the silicon substrate 10, source/drain electrodes 92, 94 are formed, and in the channel regions contacting these electrodes, LDD layers 62, 64 are formed. In the present embodiment, the gate electrode G24 corresponds, for example, to the first electrode; the tungsten thin film 75 corresponds, for example, to a first metal thin film; the tungsten nitride 83 corresponds, for example, to the compound which controls the reaction of the first metal and polycrystalline silicon.

In the damascene gate type semiconductor device 9 as in the present embodiment, similarly to the embodiment described above, between the tungsten (W) film 75 and the polycrystalline silicon 91 in the gate electrode G24 out of the gate electrodes G22, G24 of the transistors constituting the CMOS, there is formed the tungsten nitride (WN) 83 which is a compound to restrain the reaction between these members, so that the gate electrodes G22, G24 are formed to have mutually different work functions. This results in a decrease in the threshold value of the CMOS transistor and enhanced performance of the semiconductor device 9. The method of manufacturing the semiconductor device 9 shown in FIG. 24 is as follows.

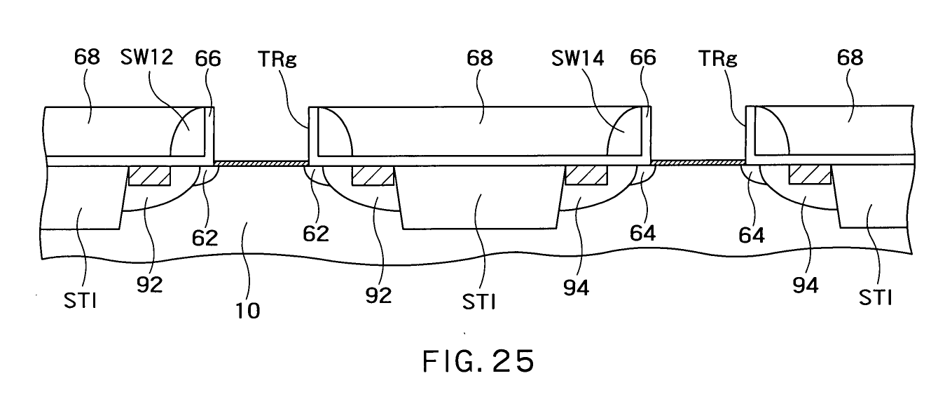

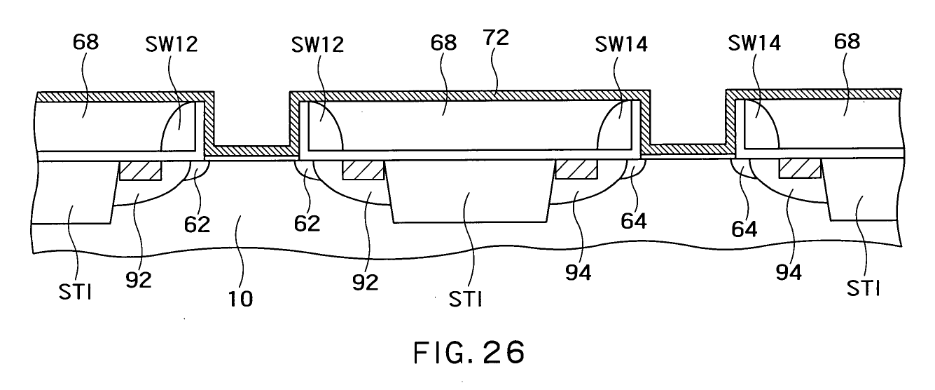

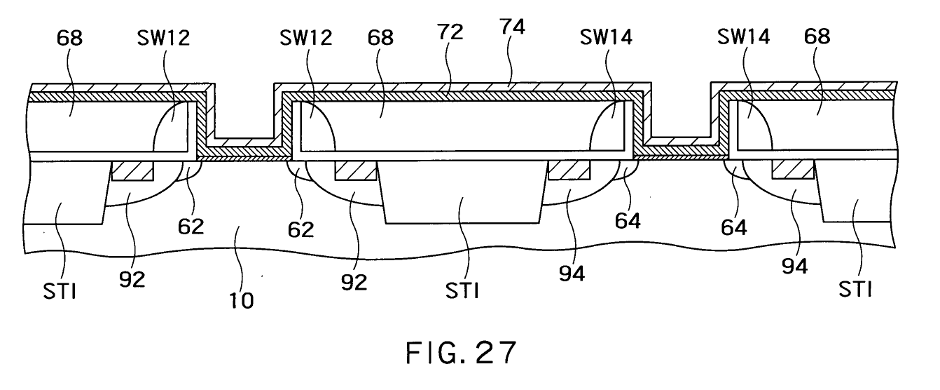

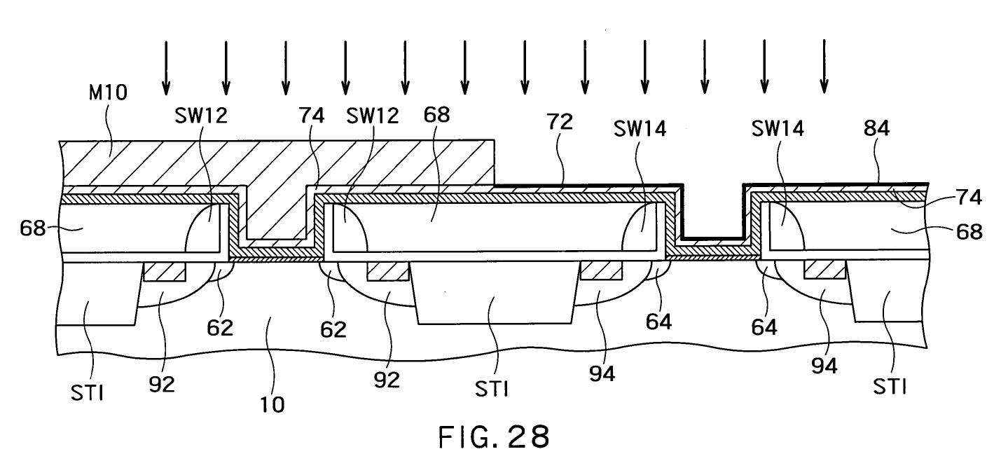

First, the STI is formed in the surface part of the silicon substrate 10 in a known manner similarly to the embodiments described above. Next, the silicon oxide film is formed as the buffer film all over the surface. The polycrystalline silicon/silicon nitride film is formed as a dummy gate film all over the surface. Dummy gate electrodes are formed by the resist and the anisotropic etching. Subsequently, after the impurity diffused layers 62, 64 having an LDD structure are formed in a known manner, the sidewalls SW12, SW14 are formed around the dummy gate electrodes. Then, impurities are injected using these sidewalls SW12, SW14 as the masks, and the impurity diffused layers 92, 94 which will be the source/drain electrodes are formed in a self-aligning manner. The impurities are activated by the thermal process. After silicide is formed in the source/drain electrodes as necessary, for example, the silicon oxide film is deposited all over the surface. The deposited silicon oxide film is etched and planarized by the CMP method or an etch back method, and an upper surface of the dummy gate insulating film is exposed. The silicon nitride film and the polycrystalline silicon film are etched and a buffer oxide film is removed by a dilute hydrofluoric acid based solution, so that the silicon substrate 10 in the region of the dummy gate is exposed as shown in FIG. 25, thereby completing the gate trench TRg to form the gate electrodes. Next, as shown in FIG. 26, an insulating film is formed in the gate trench TRg. To that end, for example, the silicon substrate 10 may be oxidized, or the high dielectric film may be deposited all over the surface. Next, as shown in FIG. 27, a tungsten (W) thin film 74 is formed at a thickness of about 5 to about 10 nm by a CVD method or the like. Subsequently, as shown in FIG. 28, the silicon oxide film is deposited as the mask material all over the surface. The mask material is removed by the patterning and etching using the resist only in the desired region (e.g., the PMOS region) so that a mask silicon oxide film M10 remains only in the NMOS region. Then, the exposed surface of a tungsten (W) thin film 74 is nitrided by the plasma treatment or the like. Finally, the silicon oxide film mask M10 is removed by the dilute hydrofluoric acid treatment or the like, thereby completing the surface nitriding of the tungsten thin film in the desired region and forming a tungsten nitride (WN) 84.

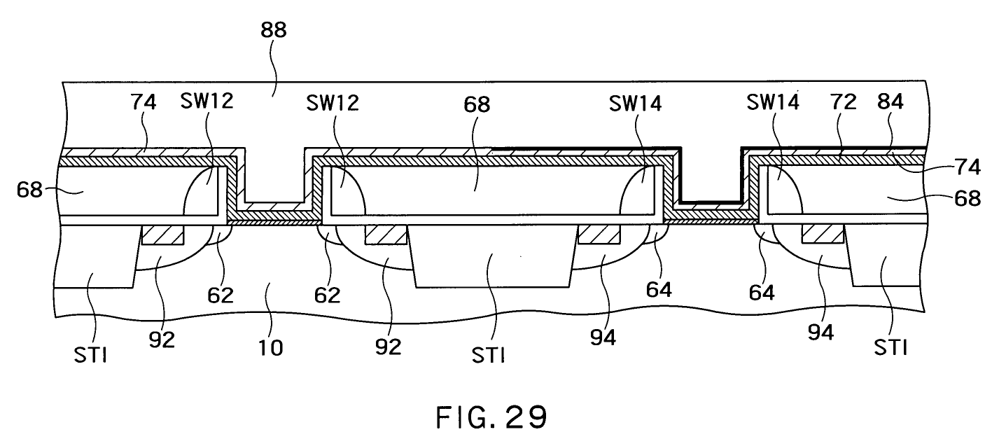

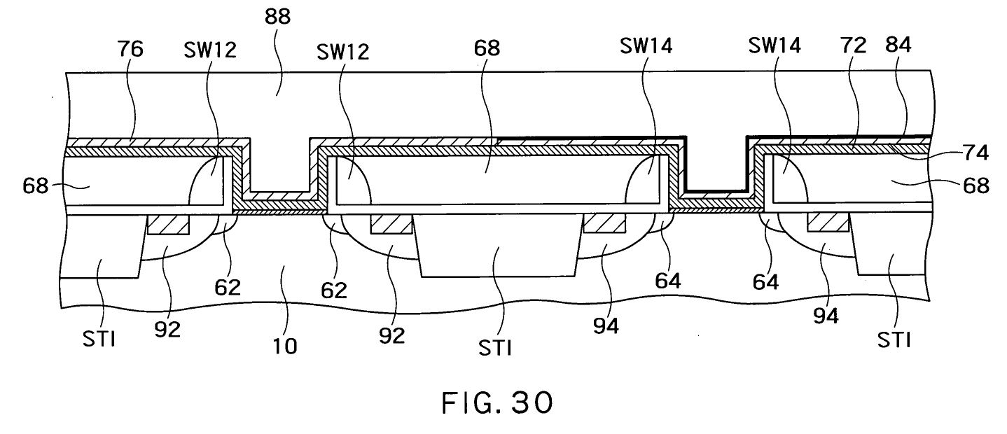

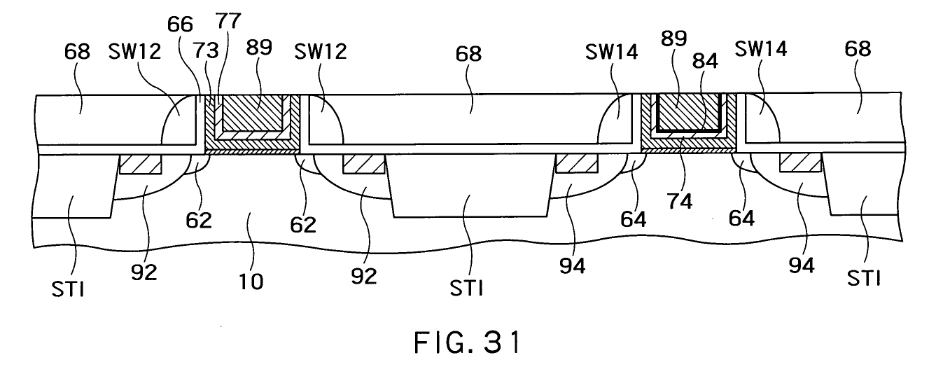

Next, as shown in FIG. 29, a polycrystalline silicon 88 is formed all over the surface. By applying heat at 650° C. or higher, the tungsten (WN) thin film 74 whose surface is not nitrided reacts with the polycrystalline silicon 88 to become a tungsten silicide film (WSix) 76, as shown in FIG. 30. On the other hand, the tungsten (WN) thin film 74 whose surface is nitrided in the region of a PMOS transistor 9 does not react with silicon because of a barrier of the tungsten nitride (WN) film 84. The polycrystalline silicon 88, the tungsten silicide film (WSix) 76, the tungsten nitride (WN) film 84 and the tungsten thin film 74 are etched and planarized by the CMP or the like, thereby obtaining the gate shape as shown in FIG. 31.

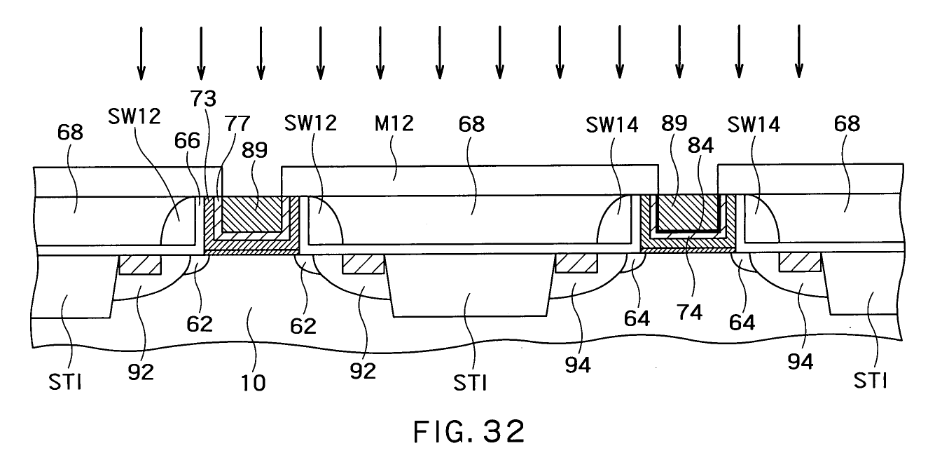

Next, as shown in FIG. 32, after the patterning using a resist M12 and the like, impurities are introduced into a polycrystalline silicon 89 of each gate. It is to be noted that the polycrystalline silicon film into which impurities have previously been introduced (e.g., P-doped polycrystalline silicon) may be used. The impurities are diffused by applying the thermal process. In this case, a low temperature at about 500° C. works sufficiently only for the mere diffusion. Then, a metal material such as nickel (Ni) is formed all over the surface to cause a silicide reaction for the reduced resistance of the gate electrodes G22, G24. Alternatively, impurities can be introduced at a high concentration without using silicide, and activated to reduce the resistance.

Subsequently, the interlayer film is deposited all over the surface as in the ordinary transistor forming process, and then the contact wires are formed to complete the transistor.

In the present embodiment, similarly to the second embodiment, a platinum silicide electrode containing tungsten (WxPtySiz) can be used instead of the tungsten electrode. In the present embodiment, since the metals such as tungsten (W) and platinum (Pt) are processed by the CMP method instead of the RIE method, there is no concern for overetching. There is also an advantage that the activating step in the source/drain region can be performed at a higher temperature.

While some of the embodiments of the present invention have been described above, the present invention is not at all limited to the embodiments above, and various modifications can be made within the technical scope thereof. For instance, the mask material to cause the surface of the tungsten thin film nitrided is not limited to the silicon oxide film. Moreover, the material of the metal thin film is not limited to tungsten. In the embodiments described above, the mode of controlling the reaction of the metal thin film and polycrystalline silicon includes restraining the reaction between them by a nitriding treatment, but the controlling mode may include promotion contrary to restraint, so that the surface treatment such as amorphism may be implemented to promote the reaction with silicon regarding the kind of metal that does not react with silicon. Further, the method of forming the LDD layers may include impurity introduction after forming narrow sidewalls around the gate, instead of using the gate electrodes and the dummy gate electrodes as the masks. Still further, amorphous silicon can be used instead of polycrystalline silicon. Further yet, the kind of substrate is not limited to the silicon substrate, and for example, a substrate using SOI can also form the semiconductor device according to the present invention. It is to be noted that depending on the film thickness and application of SOI, characteristics of the transistor may be better if the electrodes of the conductivity type in which the NMOS and PMOS are reversed to those in the present embodiment are used.

What is claimed is:

1. A semiconductor device comprising:
a substrate having a silicon layer on at least a surface thereof;
an insulating film formed on the silicon layer;
a first electrode formed on the insulating film and including a first metal thin film and a film having silicon formed on the first metal thin film; and
a second electrode formed on the insulating film and including a metal silicide which is an alloy of the first metal and silicon, and a film having silicon formed on the metal silicide,
wherein the first electrode further includes a compound which controls a reaction of the first metal and the silicon, and the compound being formed on a surface of the first metal thin film.

2. The semiconductor device according to claim 1,
wherein the film having silicon includes any of polycrystalline silicon, amorphous silicon and a metal silicide.

3. The semiconductor device according to claim 1,
wherein the film included in the second electrode at least partially includes a metal silicide.

4. The semiconductor device according to claim 1,
wherein the first metal thin film comprises a first metal and the compound is a compound of the first metal and nitrogen.

5. The semiconductor device according to claim 1,
wherein the metal silicide includes impurities.

6. The semiconductor device according to claim 1,
wherein the first metal is tungsten (W) and the compound is tungsten nitride (WN).

7. A semiconductor device comprising:
a substrate having a silicon layer on at least a surface thereof;
an insulating film formed on the silicon layer;
a first electrode formed on the insulating film and including a first metal silicide which is an alloy of a first metal, a second metal different from the first metal, and silicon; and
a second electrode formed on the insulating film and including a second metal silicide which is an alloy of the first metal and silicon.

8. The semiconductor device according to claim 7,
wherein the first electrode further includes a second metal silicide formed on the first metal silicide.

9. The semiconductor device according to claim 7,
wherein the metal silicide includes impurities.

10. The semiconductor device according to claim 7,
wherein the first metal is tungsten (W), and the second metal is platinum (PT).

11. A method of manufacturing a semiconductor device comprising:
forming an insulating film on a silicon layer of a substrate having the silicon layer on at least a surface thereof;
forming a first metal thin film made of a first metal over the insulating film;
selectively subjecting a region for a first electrode to a surface treatment, the region for the first electrode being included in a first metal thin film formation region;
forming polycrystalline silicon or amorphous silicon over the substrate; and
reacting the first metal with the polycrystalline silicon or amorphous silicon in a region for a second electrode, the region for the second electrode being included in the first metal thin film region,
wherein the surface treatment is a treatment to control the reaction of the first metal and the polycrystalline silicon or of the first metal and the amorphous silicon.

12. The method of manufacturing a semiconductor device according to claim 11,
wherein the controlling treatment is a treatment to restrain the reaction of the first metal and the polycrystalline silicon or of the first metal and the amorphous silicon.

13. The method of manufacturing a semiconductor device according to claim 11,
wherein the controlling treatment is a treatment to promote the reaction of the first metal and the polycrystalline silicon or of the first metal and the amorphous silicon.

14. The method of manufacturing a semiconductor device according to claim 11, further comprising:
introducing impurities into the polycrystalline silicon or amorphous silicon; and
diffusing the impurities therein.

15. The method of manufacturing a semiconductor device according to claim 11,
wherein the first metal is tungsten (W), and
the restraining treatment is a treatment to form a compound of tungsten nitride (WN).

16. A method of manufacturing a semiconductor device, comprising:
forming an insulating film on a silicon layer of a substrate having the silicon layer on at least a surface thereof;
forming a metal silicide including a first metal over the insulating film;
selectively forming a thin film including a second metal in a part of a region on the metal silicide, the second metal being able to react with the first metal; and
reacting a metal silicide including the first metal with the thin film including the second metal to form an alloy having a work function different from a work function of the first metal.

17. The method of manufacturing a semiconductor device according to claim 16,
wherein the second metal is platinum (PT).
